(19) United States
(12) Patent Application Publication
(10) Pub. No.: US 2024/0421771 A1
(43) Pub. Date: Dec. 19, 2024

(54) ELECTRICAL CIRCUIT, SINGLE-ENDED AMPLIFIER, AND OPERATING METHOD OF AN ELECTRICAL CIRCUIT

(71) Applicant: Robert Bosch GmbH, Stuttgart (DE)

(72) Inventors: Lucian Vasile Stoica, Nandlstadt (DE); Florin Burcea, Muenchen (DE)

(21) Appl. No.: 18/738,260

(22) Filed: Jun. 10, 2024

(30) Foreign Application Priority Data
Jun. 16, 2023 (DE) 10 2023 205 642.9

(51) Int. Cl. H03F 1/02; H03F 3/45

(52) U.S. Cl. CPC H03F 1/0205; H03F 3/45269

(57) ABSTRACT

An electrical circuit. The electrical circuit includes a first operational amplifier including a first non-inverting input, a first inverting input and a first output, a second operational amplifier including at least one second non-inverting input and a second output, and a third operational amplifier including at least one third inverting input and a third output. A feedback path includes a series circuit including a resistor, a second resistor, and a second capacitor. The feedback path is arranged between the third output and the at least one third inverting input. A first feedback path including a first series circuit with a first resistor and a first capacitor. The first feedback path is arranged between a node and the at least one second non-inverting input. The node is arranged between the resistor and the second resistor.

### CROSS REFERENCE

The present application claims the benefit under 35 U.S.C. § 119 of German Patent Application No. DE 10 2023 205 642.9 filed on Jun. 16, 2023, which is expressly incorporated herein by reference in its entirety.

### FIELD

The present invention relates to an electrical circuit, a single-ended amplifier, and an operating method of an electrical circuit.

### BACKGROUND INFORMATION

Cascaded, multi-stage operational amplifiers are used for the evaluation and further processing of sensor signals in the fields of consumer devices, inertial navigation, vehicle safety systems, and stability control systems in cameras and camcorders. For increasing the overall gain and bandwidth of cascaded, multi-stage operational amplifiers and reducing their power consumption, nested Miller compensation circuits are often used.

In order to ensure the stability of the circuit, the zeros in the right half-plane of a pole/zero diagram must be eliminated. For this purpose, active compensation structures are often used. The disadvantage here is that they increase the power consumption of the circuit.

An object of the present invention is to overcome this disadvantage.

### SUMMARY

According to an example embodiment of the present invention, an electrical circuit includes a first operational amplifier having a first non-inverting input, a first inverting input and a first output, a second operational amplifier having at least one second non-inverting input and a second output, and a third operational amplifier having at least one third inverting input and a third output. According to the present invention, a feedback path comprises a series circuit comprising a resistor, a second resistor and a second capacitor, wherein the feedback path is arranged between the third output and the at least one third inverting input. In addition, the electrical circuit comprises a first feedback path which has a first series circuit with a first resistor and a first capacitor, wherein the first feedback path is arranged between a node and the at least one second non-inverting input, wherein the node is arranged between the resistor and the second resistor. In other words, it is a three-stage operational amplifier with a nested Miller compensation that comprises two nested Miller compensation loops comprising three resistors and two capacitors.

An advantage here is that the stability is high together with high overall gain and high bandwidth. In addition, it is advantageous that the size of the circuit is small and reliable analog signal processing is ensured. Furthermore, the low power consumption of the electrical circuit is advantageous. Another advantage is that the first resistor and the second resistor are not subject to any matching conditions.

In a development of the present invention, the third operational amplifier has a third transconductance, wherein the resistance has a value which is substantially inversely proportional to the third transconductance gm3 and a sum of the resistance and of the second resistance is greater than 1/gm3. The term “substantially” in this context means that minor process fluctuations are also included here.

An advantage here is that the resistor, the first resistor, the second resistor, the first capacitor and the second capacitor are not subject to exact matching requirements so that the electrical circuit is robust as regards process variations and mismatching.

In a further example embodiment of the present invention, the resistor, the first resistor and the second resistor are each designed as a transistor in which a gate-source voltage is greater than a threshold voltage of the transistor and the gate-drain voltage is greater than or equal to the threshold voltage of the transistor. In other words, the transistors are operated in the triode range.

It is advantageous here that resistor performance is improved.

In a further development of the present invention, the first operational amplifier has a differential amplifier with a first transistor and a second transistor, a first current mirror circuit with a fifth transistor, a sixth transistor, a seventh transistor and an eighth transistor, and a cascode circuit with a ninth transistor and a tenth transistor.

An advantage here is that inexpensive components can be used.

In a development of the present invention, the second operational amplifier has a thirteenth transistor, a fourteenth transistor and a second current mirror circuit with a fifteenth transistor and a sixteenth transistor.

It is advantageous here that the silicon area of the second operational amplifier is small.

In a further embodiment of the present invention, the third operational amplifier has a seventeenth transistor and an eighteenth transistor.

An advantage here is that the third operational amplifier is of low complexity.

The single-ended amplifier according to the present invention comprises an electrical circuit according to the present invention.

An operating method according to the present invention of the electrical circuit according to the present invention has a first operating mode, which delivers a high stability, and a second operating mode, which delivers a low consumption.

An advantage here is that the electrical circuit can be used in different scenarios.

Further advantages can be found in the disclosure herein of exemplary embodiments of the present invention.

### BRIEF DESCRIPTION OF THE DRAWINGS

The present invention is explained below with reference to preferred example embodiments and the figures.

FIG. 1 shows a small-signal equivalent circuit diagram of an electrical circuit according to an example embodiment of the present invention.

FIG. 2 shows a block diagram of the electrical circuit according to an example embodiment of the present invention.

FIG. 3 shows an application example of the electrical circuit according to an example embodiment of the present invention,

FIG. 4 shows a table with various nested Miller compensation structures.

### DETAILED DESCRIPTION OF EXAMPLE EMBODIMENTS

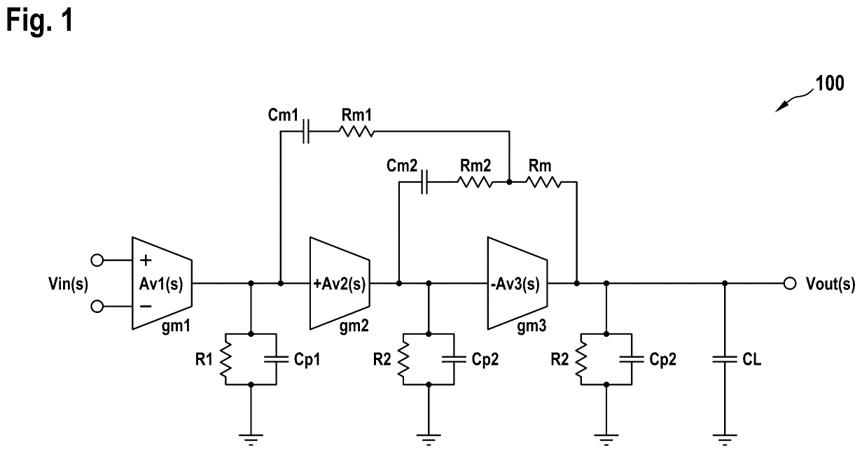

FIG. 1 shows a small-signal equivalent circuit diagram of the electrical circuit 100 according to the present invention. The electrical circuit 100 comprises a first operational amplifier Av1 with a first non-inverting input and an inverting input, as well as a first output. The first output is electrically connected to a second non-inverting input of a second operational amplifier Av2. The second operational amplifier Av2 has a second output. The second output is electrically connected to a third inverting input of a third operational amplifier Av3. The electrical circuit 100 comprises a feedback path which comprises a series circuit with a resistor Rm, a second resistor Rm2 and a second capacitor Cm2. This feedback path is arranged between the third output and the third inverting input. In addition, the electrical circuit 100 comprises a first feedback path with a first series circuit, which comprises a first resistor Rm1 and a first capacitor Cm1. The first feedback path is arranged between a node, which is arranged between the resistor Rm and the second resistor, and the second non-inverting input. The first capacitor Cm1 and the second capacitor Cm2 act as compensation capacitances. The resistors R1, R2 and R3 act as output resistances of the respective amplifier stage. The capacitors Cp1, Cp2 and Cp3 act as parasitic capacitances of the respective amplifier stage. The capacitor CL represents the load capacitance. In the exemplary embodiment shown, the first amplifier stage is non-inverting.

The second amplifier stage is non-inverting and the third amplifier stage is inverting in order to ensure negative feedback via the two compensation capacitors.

The first operational amplifier Av1 has a first transconductance gm1, the second operational amplifier Av2 has a second transconductance gm2, and the third operational amplifier Av3 has a third transconductance gm3.

In the design of stable amplifiers, a high quality, i.e., figure of merit (FOM), is required. This is calculated as follows:

$$\begin{matrix}FOM = ( GBW \cdot {C}_{L} ) / {I}_{DC} , & [ MHz \cdot pF / mA ] ,\end{matrix} \qquad ( 1 )$$

where GBW is the gain bandwidth, CL is the output load, and IDC is the DC power consumption. The gain bandwidth is determined by the transconductance gm1 of the first operational amplifier Av1 of the electrical circuit. The quality is inversely proportional to the bias current IBIAS.

The overall gain of a three-stage operational amplifier in the open control loop is given by:

$$Av ( s ) = Z 3 R ( s ) / P 3 R ( s ) \qquad ( 2 )$$

where the overall gain Av(s) is the product of the transfer function of the individual operational amplifiers, Z3R(s) is the numerator polynomial of the pole-zero transfer function, and P3R(s) is the denominator polynomial of the pole-zero transfer function. Since the frequency compensation network according to the present invention comprises the two compensation capacitors Cm1 and Cm2, as well as the resistor Rm, the first resistor Rm1 and the second resistor Rm2, the numerator polynomial of the pole-zero transfer function of the electrical circuit 100 according to the present invention is given by:

$${Z}_{3 R} ( s ) = 1 + s [ {C}_{m 1} ( {R}_{m 1} + {R}_{m} ) + {C}_{m 2} ( {R}_{m 2} + {R}_{m 1} {g}_{m 3} ) ] + {s}^{2} [ {C}_{m 1} {C}_{m 2} ( {g}_{m 2} {g}_{m 3} {R}_{m 1} {R}_{m 2} - {g}_{m 2} {R}_{m 1} - 1 ) ( {g}_{m 3} {R}_{m} - 1 ) ] / ( {g}_{m 2} {g}_{m 3} ) \qquad ( 3 )$$

The electrical circuit 100 according to the present invention, hereinafter also referred to as an NMC-3R amplifier, has a zero in the left half-plane and a zero in the right half-plane of the complex plane in which the poles and zeros are represented.

The zero in the left half-plane is given by:

$${z}_{LHP} = \{ \frac{1}{2 {C}_{m 1} {C}_{m 2}} {g}_{m 2}^{2} {g}_{m 3}^{2} ( 1 - {g}_{m 3} {R}_{m} ) ( 1 + {g}_{m 2} {R}_{m 1} - {R}_{m 1} {R}_{m 2} ) \cdot ( \frac{{C}_{m 2}}{{g}_{m 3}} - {C}_{m 1} {R}_{m} - {C}_{m 2} {R}_{m} - {C}_{m 1} {R}_{m 1} - {C}_{m 2} {R}_{m 2} - \sqrt{( {( - \frac{{C}_{m 2}}{{g}_{m 3}} + {C}_{m 1} {R}_{m} + {C}_{m 2} {R}_{m} + {C}_{m 1} {R}_{m 1} + {C}_{m 2} {R}_{m 2} )}^{2} - \frac{4 {C}_{m 1} {C}_{m 2}}{{g}_{m 2}^{2} {g}_{m 3}^{2} ( 1 - {g}_{m 3} {R}_{m} ) ( 1 + {g}_{m 2} {R}_{m 1} - {R}_{m 1} {R}_{m 2} )} )} ) \cdot \} \qquad ( 4 )$$

The zero in the right half-plane is given by:

$${z}_{RHP} = \{ \frac{1}{2 {C}_{m 1} {C}_{m 2}} {g}_{m 2}^{2} {g}_{m 3}^{2} ( 1 - {g}_{m 3} {R}_{m} ) ( 1 + {g}_{m 2} {R}_{m 1} - {R}_{m 1} {R}_{m 2} ) \cdot ( \frac{{C}_{m 2}}{{g}_{m 3}} - {C}_{m 1} {R}_{m} - {C}_{m 2} {R}_{m} - {C}_{m 1} {R}_{m 1} - {C}_{m 2} {R}_{m 2} + \sqrt{( {( - \frac{{C}_{m 2}}{{g}_{m 3}} + {C}_{m 1} {R}_{m} + {C}_{m 2} {R}_{m} + {C}_{m 1} {R}_{m 1} + {C}_{m 2} {R}_{m 2} )}^{2} - \frac{4 {C}_{m 1} {C}_{m 2}}{{g}_{m 2}^{2} {g}_{m 3}^{2} ( 1 - {g}_{m 3} {R}_{m} ) ( 1 + {g}_{m 2} {R}_{m 1} - {R}_{m 1} {R}_{m 2} )} )} ) \cdot \} \qquad ( 5 )$$

This means that the zero in the right half-plane is determined by the interaction of the current flowing from the third output to the inputs of the second operational amplifier and of the third operational amplifier and of the frequency-dependent drive current flowing from the second non-inverting input of the second operational amplifier via the first capacitor Cm1 and the first resistor Rm1 to the third output and from the third inverting input of the third operational amplifier via the second capacitor Cm2 and the second resistor Rm2 to the third output. If the zero function of the right half-plane increases, the phase reserve or phase margin decreases and the stability decreases. For stable operation of the electrical circuit 100, the zero in the right half-plane must be eliminated. For this reason, the number of zeros must be minimized. For this to happen, the s² coefficient must be zero and the s coefficient in equation (3) must be greater than zero.

For this reason, in one exemplary embodiment, the resistance Rm=1/gm3 and the sum of the second resistance Rm2 and the resistance Rm are selected to be greater than 1/gm3. This means that zero elimination in the right half-plane no longer depends solely on the optimal resistance value Rm, since the first resistor Rm1 and the second resistor Rm2 minimize the drive current that generates the zeros in the right half-plane. This increases the phase value. This means that the third transconductance gm3 can vary over a wider range without affecting the stability of the amplifier circuit.

In another exemplary embodiment, the value of the first capacitor Cm1 is reduced, thereby increasing the overall gain and the figure of merit. At the same time, the area required for the electrical circuit 100 is reduced. In order to prevent a reduction in the phase value, the values of the first resistance Rm1 and of the second resistance Rm2 can optionally be increased.

In another exemplary embodiment, the resistance Rm is increased so that the zero in the right half-plane assumes a very large value. In another exemplary embodiment, the resistance Rm is increased further so that the zero in the right half-plane drifts or shifts to the left half-plane. This increases the phase value and improves stability.

In a further exemplary embodiment, the resistor Rm, the first resistor Rm1 and the second resistor Rm2 can in each case be designed as a transistor in which a gate-source voltage is greater than a threshold voltage of the transistor and the gate-drain voltage is greater than or equal to the threshold voltage of the transistor. They are therefore operated in the triode range.

In all exemplary embodiments, the compensation capacitors Cm1 and Cm2 can be ascertained via the amplifier poles of a third-order Butterworth frequency response at a unity gain.

The electrical circuit 100 has two preferred operating modes. The first operating mode has a high stability of the electrical circuit 100, the so-called stability mode, and the second operating mode has a low power consumption of the electrical circuit 100, the so-called energy-saving mode. The circuitry of the electrical circuit 100 is the same in both cases. In stability mode, the phase reserve is greater, while the FOM is somewhat lower due to the higher power consumption. This mode is used for high-speed signal processing, for example in switching circuits with switched capacitors and high clock frequencies.

In energy-saving mode, the gain bandwidth GBW, the phase reserve, the slew rate SR+ and the settling time are lower. The power consumption is 26% lower, resulting in a higher FOM. This mode is used for applications with low power consumption.

In other words, the transistors are dimensioned such that they are biased into saturation for the lowest possible power consumption, while the frequency compensation elements Cm1, Cm2, Rm1, Rm2, Rm are dimensioned such that they ensure stability, i.e., phase reserve PM and gain reserve, with the smallest possible silicon size. In addition, the transistors M5-M8 have a long length in order to minimize noise. The resistance value Rm for eliminating the RHP zero is set independently of the resistors Rm1 and Rm2. A good adjustment, i.e., matching of the first resistor Rm1 and the second resistor Rm2, is no longer necessary. In terms of stability, i.e., phase reserve, a higher Rm value can replace a lower value of gm3, i.e., lower current through the eighteenth transistor M18, so that the power consumption is lower. These are great advantages in analog IC design.

The electrical circuit 100 can be used in charge-measuring amplifiers or signal conditioning blocks or signal conditioning chains based on operational amplifiers. In addition, the electrical circuit 100 can be used in pseudo-differential amplifiers.

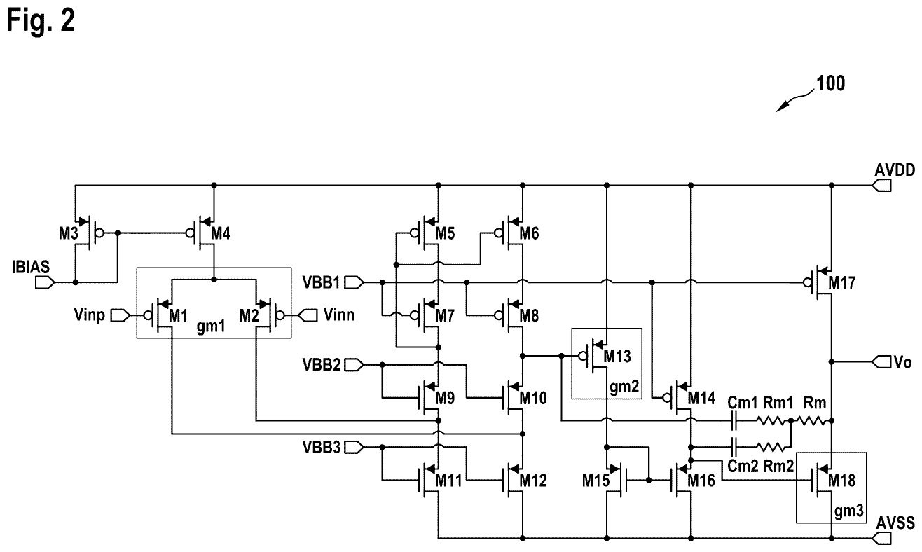

FIG. 2 shows a block diagram of the electrical circuit 100 according to the present invention. The first operational amplifier Av1 comprises a differential amplifier with a first transistor M1 and a second transistor M2, a current mirror circuit with a third transistor M3 and a fourth transistor M4, a first current mirror circuit with a fifth transistor M5, a sixth transistor M6, a seventh transistor M7 and an eighth transistor M8, a cascode circuit with a ninth transistor M9 and a tenth transistor M10, as well as a current source comprising an eleventh transistor M11 and a twelfth transistor M12. The first transistor M1 and the second transistor M2, i.e., the differential amplifier, are biased by the current mirror circuit comprising the third transistor M3 and the fourth transistor M4 and a bias current IBIAS. The input current of the first operational amplifier Av1 results from the sum of the currents of the cascode circuit at the drain terminals of the current source. The differential amplifier is designed for an input voltage range of 300-900 mV with a nominal supply voltage of 1.2 V. The input voltage range can be increased by using complementary NMOS and PMOS input pairs. In order to maximize the output signal amplitude, the input common-mode voltage VCM is set to a midpoint between AVDD and AVSS.

The second operational amplifier Av2 comprises a thirteenth transistor M13, a fourteenth transistor M14 and a second current mirror circuit with a fifteenth transistor M15 and a sixteenth transistor M16.

The third operational amplifier Av3 comprises a seventeenth transistor M17 and an eighteenth transistor M18.

The gate of the thirteenth transistor M13 acts as a second non-inverting input and is electrically connected to the drain of the tenth transistor M10 and of the eighth transistor M8, i.e., to the first output of the first operational amplifier Av1. The first output of the first operational amplifier Av1 is electrically connected to the first capacitor Cm1 and to the first resistor Rm1, i.e., to the so-called frequency compensation elements. The thirteenth transistor M13 forms the second transconductance gm2. The gate of the eighteenth transistor M18 acts as the third inverting input of the third operational amplifier Av3 and is electrically connected to the drain of the fourteenth transistor M14 and of the sixteenth transistor M16, i.e., to the second output of the second operational amplifier Av2. The eighteenth transistor M18 forms the third transconductance gm3. The second output of the second operational amplifier Av2 is electrically connected to the second capacitor Cm2 and to the second resistor Rm2.

The seventh transistor M7, the eighth transistor M8, the fourteenth transistor M14, and also the seventeenth transistor M17 are biased by a first voltage VBB1. The ninth transistor M9 and the tenth transistor M10 are biased by a second voltage VBB2. The eleventh transistor M11 and the twelfth transistor M12 are biased by a third voltage VBB3.

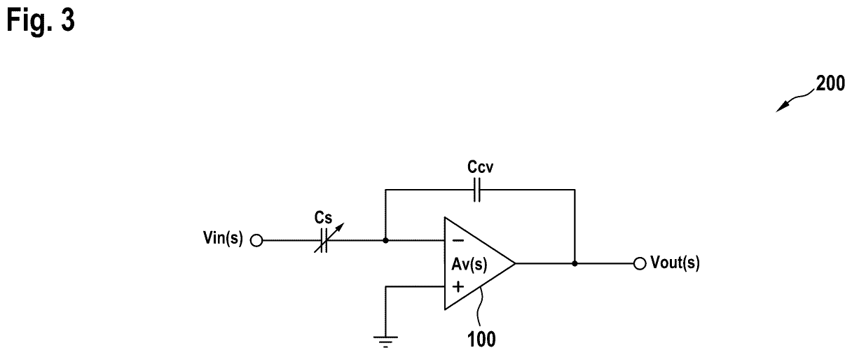

FIG. 3 shows an application example of the electrical circuit according to the present invention in the form of a C/V converter. The C/V converter 200 comprises a three-stage operational amplifier having an electrical circuit according to the present invention. The input Vin is connected to a series-connected variable capacitor Cs, which generates a differential input signal. This signal is made available to the gates of the first transistor and of the second transistor via Vinn and Vinp from FIG. 2.

With the aid of wafer-level test measurements of an ASIC, which may comprise such a C/V converter, silicon area is saved and a stable continuous output signal is generated.

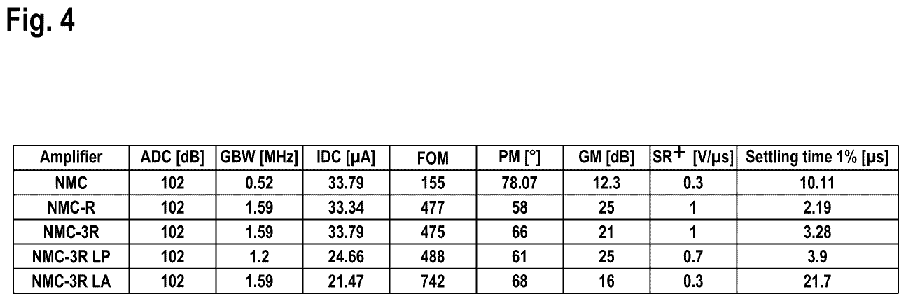

FIG. 4 shows a table comparing the simulation results of various nested Miller compensation structure configurations under nominal operating conditions. A temperature of 25° C., VDD=1.2 V, CL=10 pF and a DC current consumption of IDC were assumed. The simulated transconductances are gm1=16 μS, gm2=50 μS and gm3=314 μS. A related-art NMC, an NMC with a resistor, hereinafter referred to as NMC-R, and the electrical circuit according to the present invention, referred to as NMC-3R, are compared. Due to the absence of nulling resistors, the NMC configuration has a high phase value of 78°, but a low gain bandwidth GBW of 0.52 MHz and therefore a low FOM of 155. The NMC-R configuration has an FOM of 477, a typical phase reserve of 58° and a typical gain of 25 dB. The NMC-3R configuration has an FOM of 475, with a typical phase reserve of 66° and a typical gain of 21 dB.

This means that relative to the NMC-R configuration, the phase reserve of the NMC-3R improves by 8°. This creates better stability with a comparable FOM. The slew rate remains constant at 1 V/μs.

In order to obtain a similar phase reserve as in the case of the NMC-R configuration, the NMC-3R configuration is biased with a lower current, thus reducing the overall consumption of the circuit by 26%. This increases the FOM to 488. This configuration is listed in FIG. 4 under NMC-3R LP. In other words, it is the electrical circuit from FIG. 1 operated in energy-saving mode. The total DC power consumption is 24.66 PA.

In another variant, the resistance Rm in the NMC-3R is increased from 2.6 kΩ to 10 kΩ. This increases the phase reserve from 66° to 87°, while the gain decreases from 21 dB to 10 dB, with the output noise only increasing slightly. If the transistor width of the seventeenth transistor M17 is reduced to 12 μm/4 μm, the FOM increases to 742, while the phase reserve remains at 68°. This result is listed in FIG. 1 as NMC-3R LA. The dynamic performance of the NMC-3R LA variant is slightly lower as can be seen in the slew rate and in the settling time, but can be used for low-consumption applications. In other words, this is the electrical circuit from FIG. 1 operated in stability mode.

What is claimed is:

1. An electrical circuit, comprising:
a first operational amplifier including a first non-inverting input, a first inverting input, and a first output;
a second operational amplifier including at least one second non-inverting input, and a second output;
a third operational amplifier including at least one third inverting input, and a third output;
a feedback path including a series circuit including a resistor, a second resistor, and a second capacitor, wherein the feedback path is arranged between the third output and the at least one third inverting input; and
a first feedback path including a first series circuit including a first resistor, and a first capacitor, wherein the first feedback path is arranged between a node and the at least one second non-inverting input, wherein the node is arranged between the resistor and the second resistor.

2. The electrical circuit according to claim 1, wherein the third operational amplifier has a third transconductance gm3, and the resistor has a value which is substantially inversely proportional to the third transconductance gm3, and a sum of the value of resistor and a value of the second resistor is greater than 1/gm3.

3. The electrical circuit according to claim 1, wherein each of the resistor, the first resistor, and the second resistor is a transistor in which a gate-source voltage is greater than a threshold voltage of the transistor and a gate-drain voltage is greater than or equal to the threshold voltage of the transistor.

4. The electrical circuit according to claim 1, wherein the first operational amplifier includes a differential amplifier with a first transistor and a second transistor, a first current mirror circuit with a fifth transistor, a sixth transistor, a seventh transistor, and an eighth transistor, and a cascode circuit with a ninth transistor and a tenth transistor.

5. The electrical circuit according to claim 1, wherein the second operational amplifier includes a thirteenth transistor, a fourteenth transistor and a second current mirror circuit with a fifteenth transistor and a sixteenth transistor.

6. The electrical circuit according to claim 1, wherein the third operational amplifier includes a seventeenth transistor and an eighteenth transistor.

7. A single-ended amplifier, comprising:
an electrical circuit, including:
a first operational amplifier including a first non-inverting input, a first inverting input, and a first output,
a second operational amplifier including at least one second non-inverting input, and a second output;
a third operational amplifier including at least one third inverting input, and a third output,
a feedback path including a series circuit including a resistor, a second resistor, and a second capacitor, wherein the feedback path is arranged between the third output and the at least one third inverting input, and
a first feedback path including a first series circuit including a first resistor, and a first capacitor, wherein the first feedback path is arranged between a node and the at least one second non-inverting input, wherein the node is arranged between the resistor and the second resistor.

8. An operating method of an electrical circuit, the electrical circuit including:
a first operational amplifier including a first non-inverting input, a first inverting input, and a first output,
a second operational amplifier including at least one second non-inverting input, and a second output,
a third operational amplifier including at least one third inverting input, and a third output,
a feedback path including a series circuit including a resistor, a second resistor, and a second capacitor, wherein the feedback path is arranged between the third output and the at least one third inverting input, and
a first feedback path including a first series circuit including a first resistor, and a first capacitor, wherein the first feedback path is arranged between a node and the at least one second non-inverting input, wherein the node is arranged between the resistor and the second resistor,
the method comprising:
operating the electrical circuit in a first operating mode, which delivers a high stability; and
operating the electrical circuit in a second operating mode, which delivers a low consumption.
